(19) United States
(12) Patent Application Publication
(10) Pub. No.: US 2008/0173913 A1
(43) Pub. Date: Jul. 24, 2008

(54) SEMICONDUCTOR DEVICE

(75) Inventor: Kenji KOJIMA, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/013,646

(22) Filed: Jan. 14, 2008

(30) Foreign Application Priority Data
Jan. 12, 2007 (JP) 2007-005104

(51) Int. Cl. H01L 29/94

(52) U.S. Cl. 257/296; 257/E29.345

(57) ABSTRACT

In one aspect of the present invention, a semiconductor device may include a support member, a FinFET provided on the support member, which has a first fin, a source region provided in the first fin, a drain region provided in the first fin, and a gate electrode provided on the first fin via an gate insulating layer, and a capacitor provided on the support member, which has a second fin, a third fin and a dielectric layer provided between the second fin and the third fin.

### CROSS REFERENCE TO RELATED APPLICATION

This application is based upon and claims the benefit of priority from Japanese Patent Application No. 2007-5104, filed on Jan. 12, 2007, the entire contents of which are incorporated herein by reference.

### BACKGROUND

In a conventional semiconductor device, a transistor and a capacitor are provided in a common substrate. For example, in U.S. patent application Publication US2006/0003526, a FinFET and a capacitor which has electrodes and a dielectric layer sandwiched by the electrodes are disclosed.

When the capacitor electrode and the dielectric layer are vertically laminated as shown in the conventional semiconductor device, the size in a plan view is shrunk (reduced) and the capacitance is also reduced, since the area of the capacitance electrode is reduced.

### SUMMARY

Aspects of the invention relate to an improved semiconductor device.

In one aspect of the present invention, a semiconductor device may include a support member, a FinFET provided on the support member, which has a first fin, a source region provided in the first fin, a drain region provided in the first fin, and a gate electrode provided on the first fin via an gate insulating layer, and a capacitor provided on the support member, which has a second fin, a third fin and a dielectric layer provided between the second fin and the third fin.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a cross sectional view of a semiconductor device in accordance with a first embodiment.

FIG. 2 is a perspective view of a transistor 10 in the semiconductor device in accordance with the first embodiment.

FIG. 3 is a plan view of a transistor 10 in the semiconductor device in accordance with the first embodiment.

FIG. 4 is a cross sectional view taken along B-B line in FIG. 3.

FIG. 5 is a cross sectional view taken along C-C line in FIG. 3.

FIG. 6 is a plan view of a capacitor 50 in the semiconductor device in accordance with the first embodiment.

FIGS. 7-13 are cross sectional views showing a manufacturing process of the semiconductor device in accordance with the first embodiment.

FIG. 14 is a cross sectional view of a semiconductor device in accordance with a second embodiment.

FIGS. 15 and 16 are cross sectional views showing a manufacturing process of the semiconductor device in accordance with second first embodiment.

FIG. 17 is a cross sectional view showing a support structure of a fin in accordance with a modification.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### First Embodiment

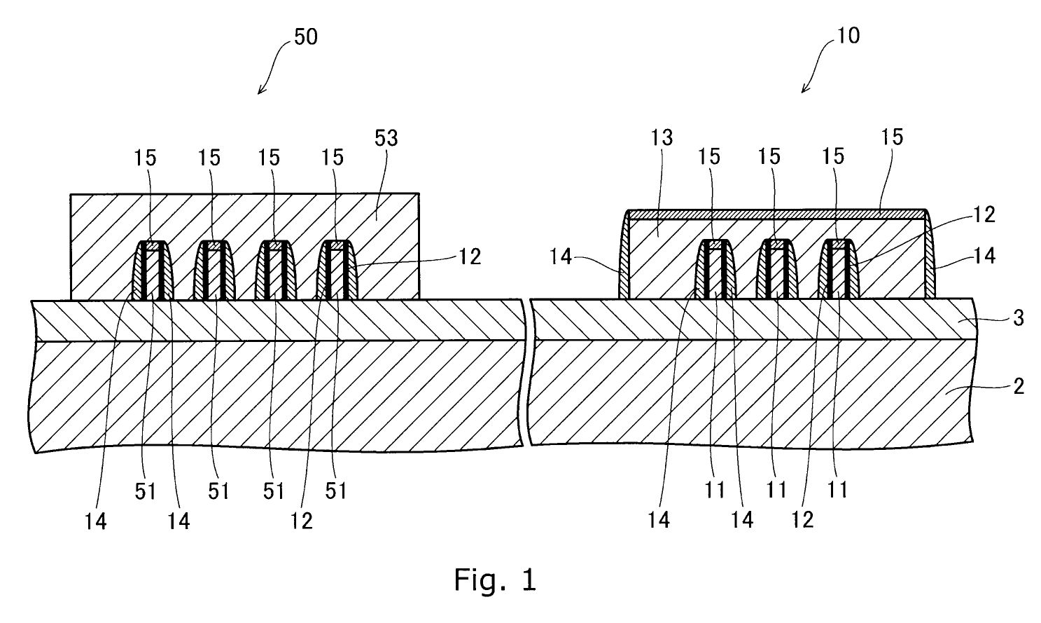

A first embodiment of the present invention will be explained hereinafter with reference to FIGS. 1-13.

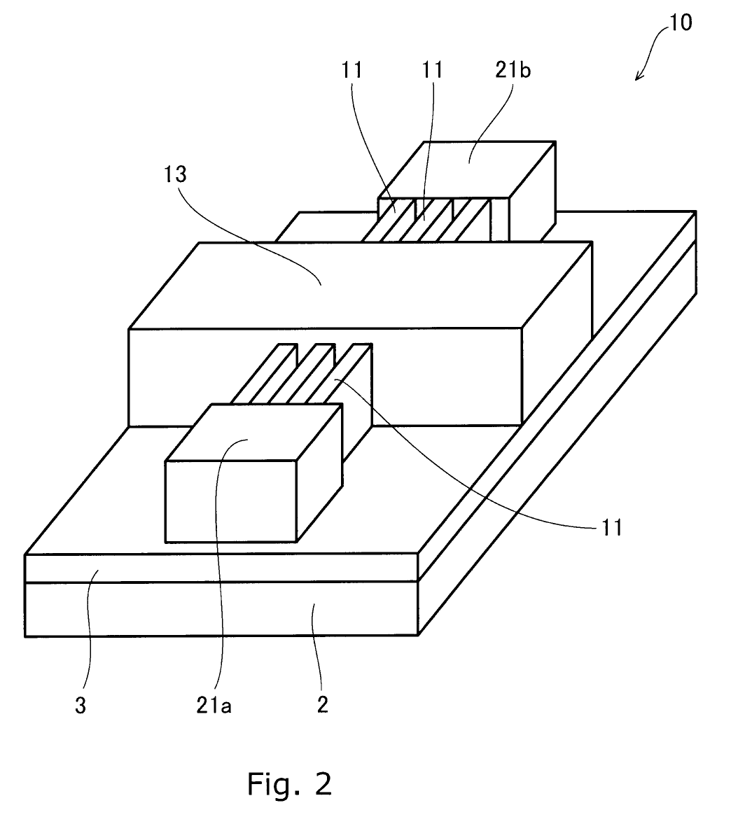

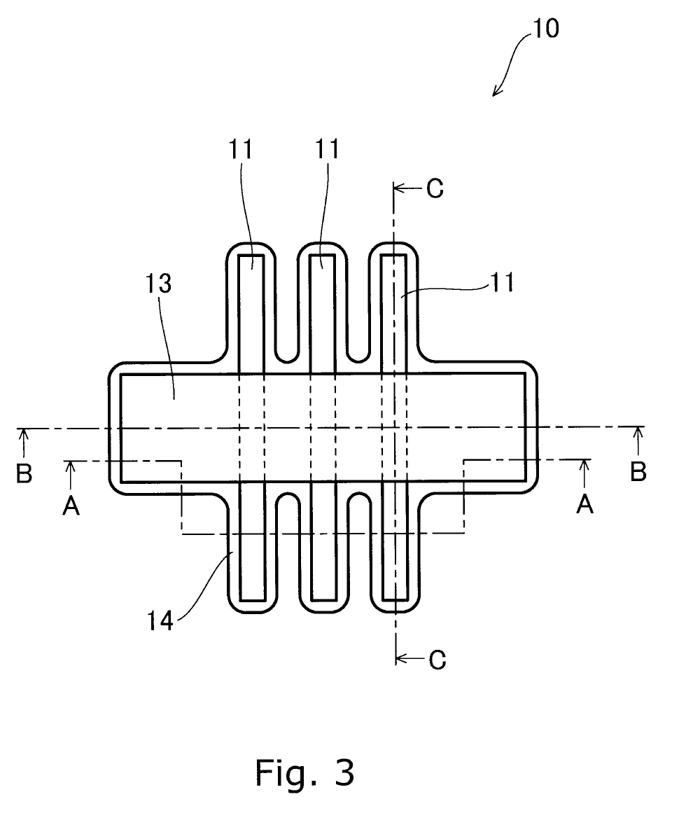

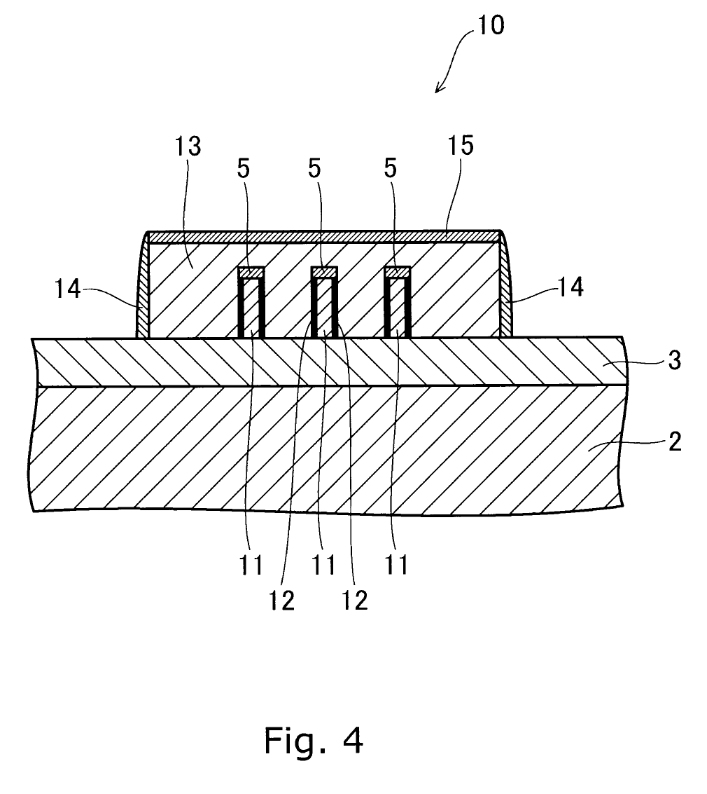

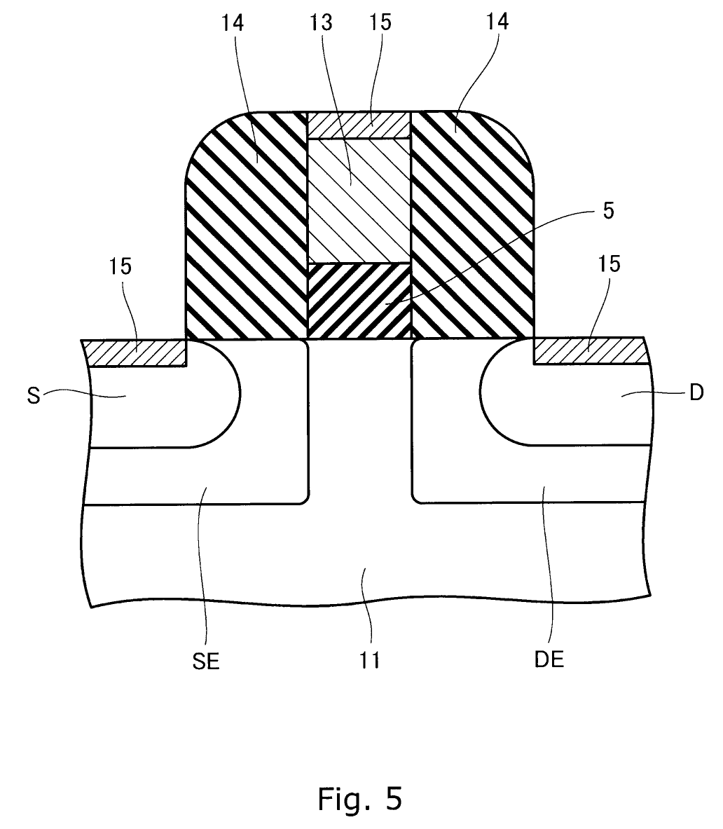

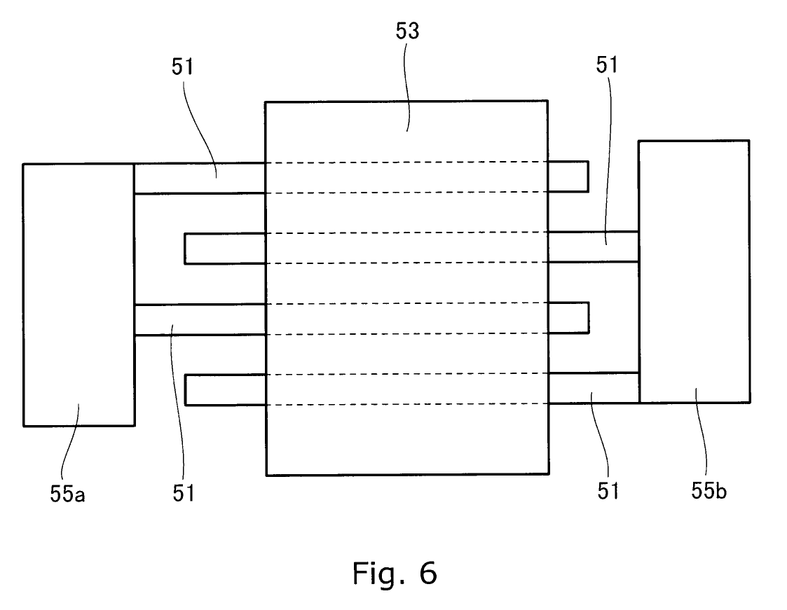

FIG. 1 is a cross sectional view of a semiconductor device in accordance with a first embodiment. FIG. 1 is corresponding to a cross sectional view taken along A-A line in FIG. 3. FIG. 2 is a perspective view of a transistor 10 in the semiconductor device in accordance with the first embodiment. FIG. 3 is a plan view of a transistor 10 in the semiconductor device in accordance with the first embodiment. FIG. 4 is a cross sectional view taken along B-B line in FIG. 3. FIG. 5 is a cross sectional view taken along C-C line in FIG. 3. FIG. 6 is a plan view of a capacitor 50 in the semiconductor device in accordance with the first embodiment.

As shown in FIG. 1, in the semiconductor device of the first embodiment, the transistor 10 and the capacitor 50 are provided on a common support member (insulating layer 3). The insulating layer 3 is a silicon oxide film provided on a semiconductor substrate 2. The transistor 10 is a FinFET in the first embodiment.

A plurality of semiconductor fins (abbreviated as fin hereinafter) 11 and 51 is provided on the insulating layer 3. A first fin 11 and a second fin 51 are protruded upward from the insulating layer 3. A current pass of transistor 10 is provided in the first fin 11. The second fin 51 functions as an electrode of capacitor 50, and the second fin 51 and neighboring fin 51 are faced each other. The first fin 11 and the second fin 51 may be made of Si. The number of the fins 11 and 51 is not limited to the number shown in FIG. 1.

The first fin 11 and the second fin 51 are substantially same width and height. The fin 11 and the second fin 51 are extended to substantially same direction as shown in FIG. 1. In FIG. 1, the fin 11 and the second fin 51 are extended to a direction perpendicular to the face of FIG. 1.

The distance between the first fins 11 and the distance between the second fins 51 are substantially same. However, the distance between the second fins 51 may be changed in accordance with the capacitance of the capacitor 50.

As shown in FIG. 5, a source region S and a drain region D are provided in the first fin 11 near the top surface of the first fin 11 in the transistor 10. A source extension region SE is provided near the source region S and a drain extension region DE is provided near the drain region D.

A gate electrode 13 is provided on the first fin 11 via an insulating layer 5. A channel is provided in the first fin 11 between the source extension SE and drain extension DE below the gate electrode 13. The gate electrode 13 may be polycrystalline Si. As shown in FIG. 2 and FIG. 3, the direction which the gate electrode 13 is extended to is perpendicular to a direction which the first fin 11 is extended to.

The gate electrode 13 is provided between the source S and drain D. As shown in FIG. 2, the source S is connected to a source electrode 21a and the drain D is connected to the drain electrode 21b.

An insulating layer 12 as a gate insulating layer is provided on a side surface of the first fin 11. The insulating layer 12 may be a silicon oxide layer formed by thermal oxide method. As shown in FIGS. 4 and 5, an insulating layer 5 is provided on a channel portion of the first fin 11. The insulating layer 5 may be a SiN. The gate electrode 13 is faced to the top and side surfaces of the channel portion of the first fin 11.

A sidewall 14 is provided on a side surface of the first fin 11 except for where the gate electrode 13 is provided. The sidewall 14 may be a SiO₂, SiN or the like. The sidewall 14 is provided on a side surface of the gate electrode 13 and an edge surface of the longitudinal direction of the gate electrode 13.

In the capacitor 50, a dielectric layer 53 is provided. The dielectric layer 53 is provided between the second fins 51. One of the second fins 52 faces next second fin 52 by the side surface. The dielectric layer 53 may be a silicon nitride (SiN), tantalum oxide (TaO₂), aluminum oxide (Al₂O₃) or the like.

As shown in FIG. 6, in a pair of the second fins 51 which are provided next to each other with sandwiching the dielectric layer 53, one of the second fins 51 is connected to an electrode (electrode pad) 55a for applying positive voltage, and the other of the second fins 51 is connected to an electrode (electrode pad) 55b for applying negative voltage. The opposite polarity voltage is applied to one fin 51 and its next fin 51. Electrical contacts are provided on the electrodes 55a and 55b, respectively.

The dielectric layer 53 is provided on a top surface of the second fin 51 via a compound layer (silicide layer) 15. The silicide layer 15 is formed by a silicidation of the fin 51 to a metal. The compound layer 15 may be a silicide layer, such as a CoSi layer, a NiSi layer, a TiSi layer or the like.

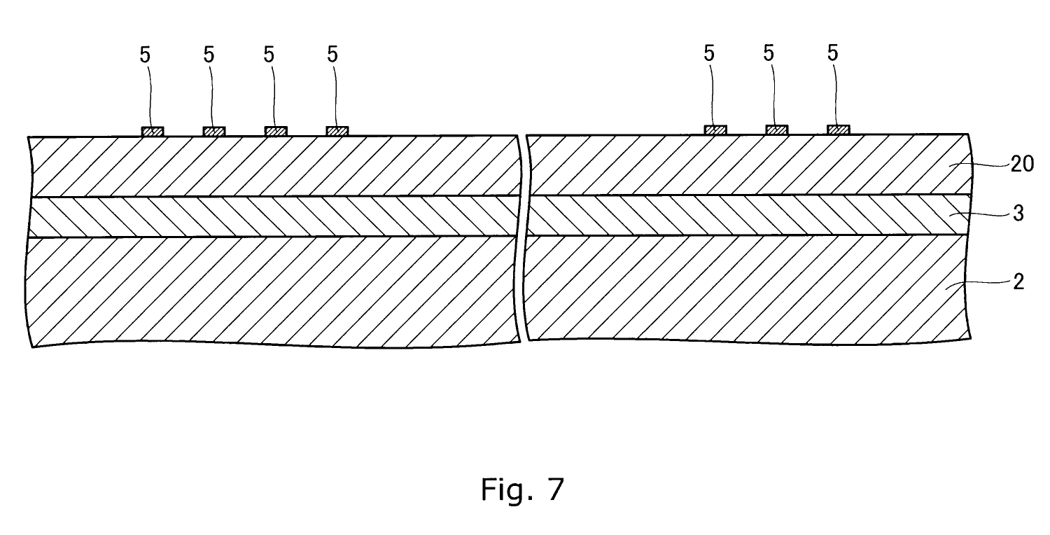

Next, a manufacturing process of the semiconductor device as shown ion FIG. 1 will be explained hereinafter with reference to FIGS. 7-13.

As shown in FIG. 7, a semiconductor layer 20 is provided on the semiconductor substrate 2 via the insulating layer 3. The semiconductor substrate and the semiconductor layer 20 may be made of Si, and the insulating layer 3 may be SiO₂.

The insulating layer 5 such as SiN is selectively provided on the semiconductor layer 20.

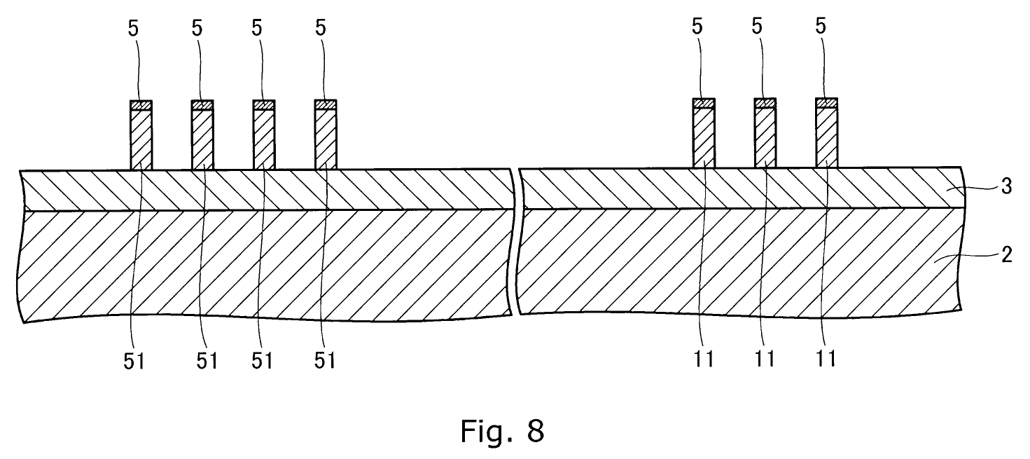

As shown in FIG. 8, the semiconductor layer 20 is removed by an RIE (Reactive Ion Etching) with the insulating layer 5 as a mask. So a plurality of the first fins 11 and the second fins 51 are provided on the insulating layer 3.

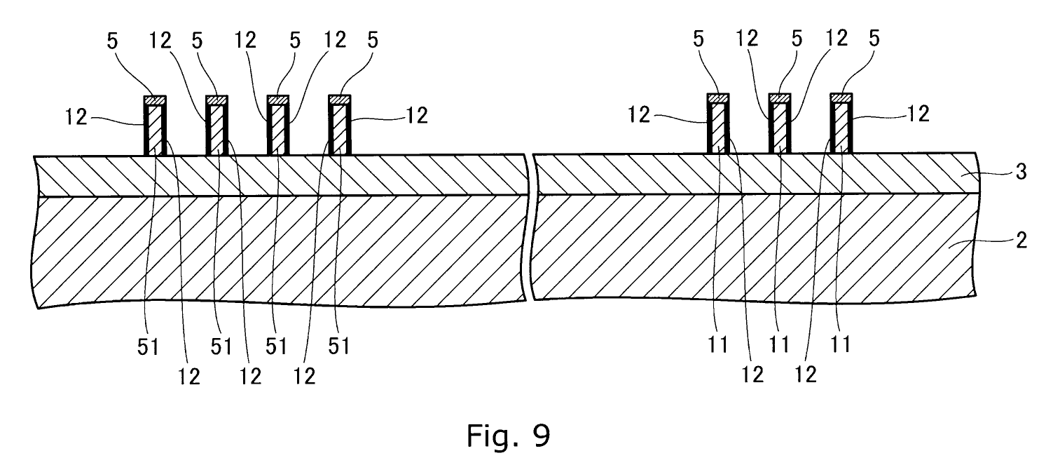

As shown in FIG. 9, the insulating layer 12 is provided on the side surface of the first fins 11 and the second fins 51 by a thermal oxidation.

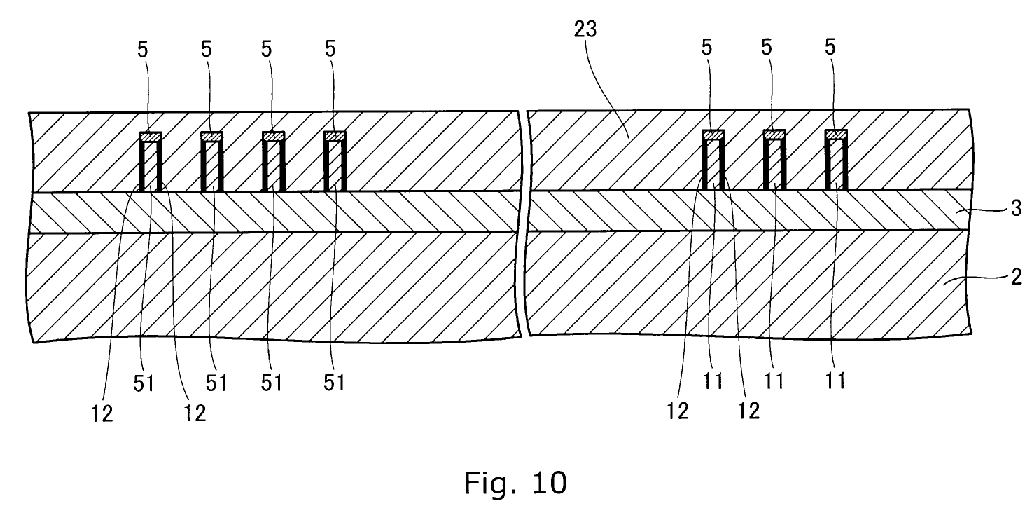

As shown in FIG. 10, a poly crystalline Si 23 is deposited on the insulating layer 3 so as to cover the first fin 11, the second fin 51 and the insulating layer 5. The poly crystalline Si 23 is planarized with polishing so as to expose the insulating layer 5.

A poly crystalline Si is deposited on the insulating layer 5 and the poly crystalline Si 23, and patterning with a resist layer is provided. The resist layer is provided on, for example, the first fin 11. The poly crystalline Si is removed by an etching and a gate electrode 13 crossing the first fin 11 as shown in FIG. 2 is provided.

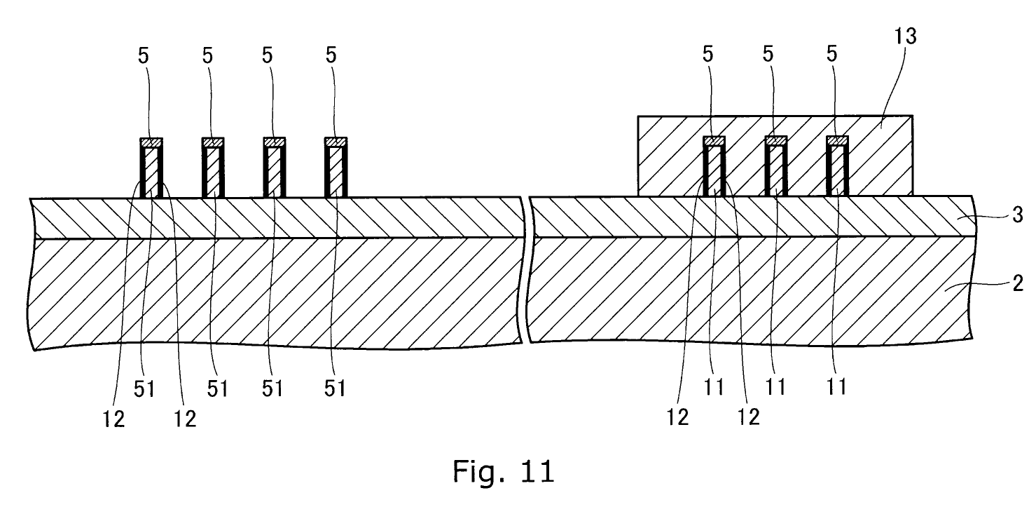

The poly crystalline Si 23 in the capacitor 50 is removed as shown in FIG. 11 and the insulating layer 5 on the second fin 51 is exposed. Furthermore, a portion of the insulating layer 5 on the first fin 11, where the gate electrode 13 is not provided, is exposed.

The portion of the insulating layer 5 on the first fin 11, where the gate electrode 13 is not provided, is removed by a wet etching or the like. A portion of the insulating layer 5 on the second fin 51, where the gate electrode 13 is not provided, is removed by a wet etching or the like.

The source extension region SE and the drain extension region DE are formed by ion implantation or plasma doping method in the first fin 11.

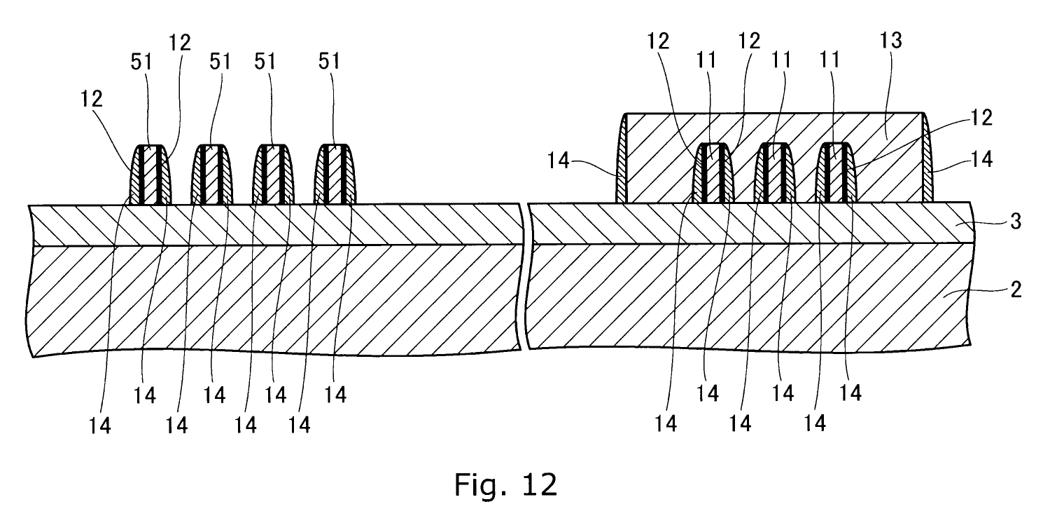

An insulating layer such as SiO₂, SiN or the like is deposited on the insulating layer 3 so as to cover the first fin 11, the gate electrode 13 and the second fin 51. After the deposition, the insulating layer is etched by RIE. So the sidewall 14 is provided as shown in FIGS. 3 and 12.

Later that, the source S and the drain D is formed by introducing an impurity with the sidewall 14 as a mask.

The impurities are implanted to the second fins 51 during a forming process of source extension region SE, drain extension region DE, source S, or drain D. So the resistance of the second fin 51 is reduced.

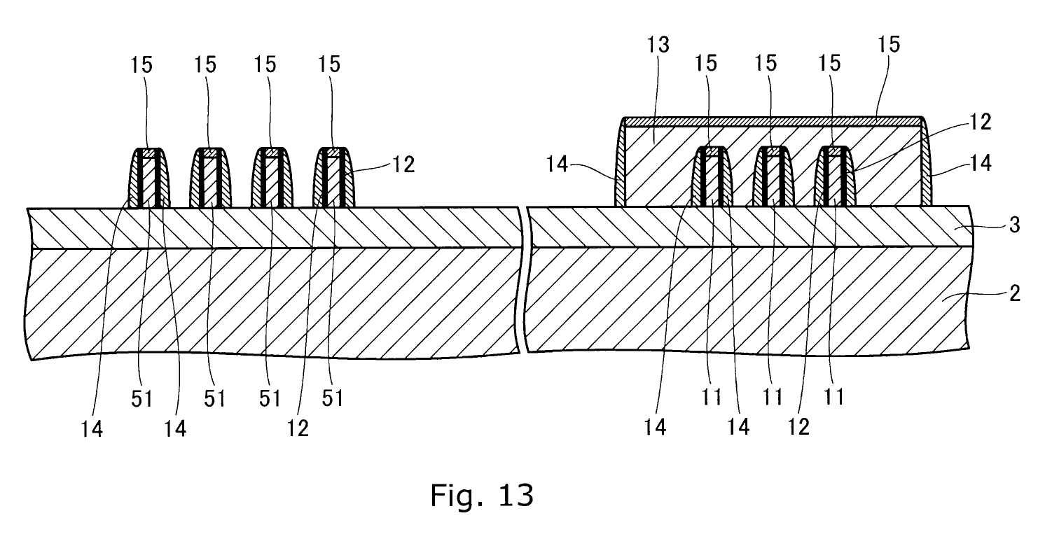

As shown in FIG. 13, the silicidation process is provided. A metal layer is provided on the entire surface of the insulating layer 3 so as to cover the first fin 11, gate electrode 13 and the second fin 51. Later that, a heat treatment is provided and the metal and Si is reacted. So the silicide layer 15 is provided on the gate electrode 13, a part of the first fin 11 on which the gate electrode 13 is not provided, and the top surface of the second fin 51. The silicide layer 15 may be CoSi layer, NiSi layer, TiSi layer, TiSi layer or the like. The resistivity of the second fin 51 is reduced by silicidation.

A dielectric layer is deposited on the insulating layer 3 so as to cover the first fin 11, gate electrode 13 and second fin 51 and selectively removed by RIE. So, as shown in FIG. 1, the dielectric layer on the transistor 10 is removed and a part of the dielectric layer 53 remains on the capacitor 50. The dielectric layer 53 is provided between the second fins 51. So the capacitor 50, which has the second fins 51 as electrodes and the dielectric layer 53 sandwiched by the second fins 51, is provided.

In the semiconductor device of this embodiment, the distance between the second fins 51 is reduced, the number of fins per unit area is increased and the area of electrode for the capacitor 50 is increased with shrinking the are size of the semiconductor elements such as transistor in a plan view. Namely, the capacitance of the capacitor 50 per unit area in a plan view is increased with the size of the semiconductor element in a plan view is shrunk.

Furthermore, the number of the manufacturing process is reduced, since the second fin 51 which is used as an electrode of the capacitor 50 and the first fin 11 which is used as FinFET 10 are formed in a same manufacturing process.

### Second Embodiment

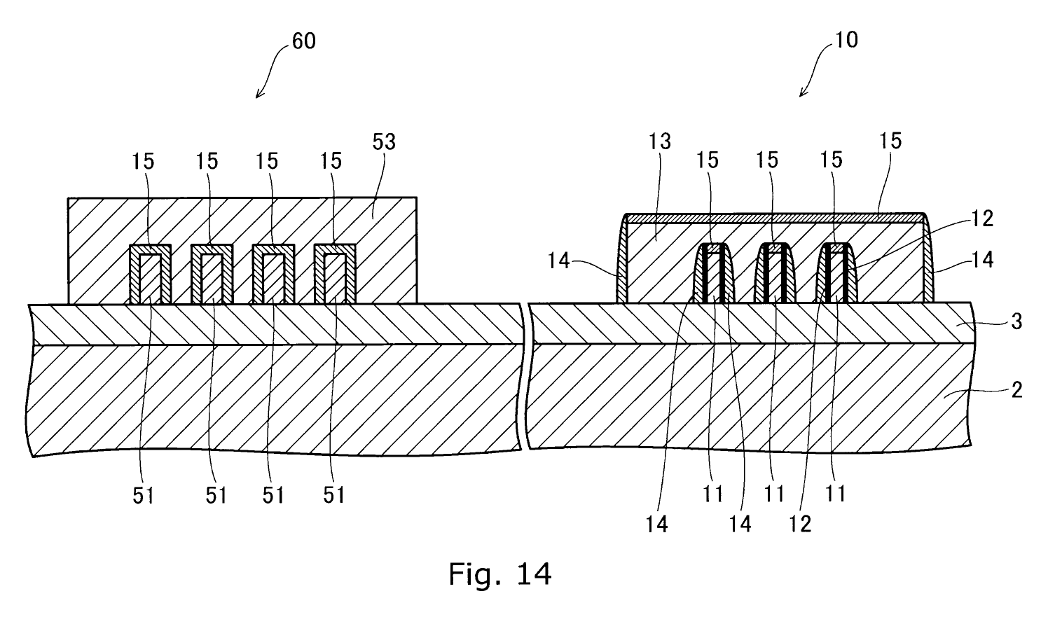

A second embodiment is explained with reference to FIGS. 14-16.

FIG. 14 is a cross sectional view of a semiconductor device in accordance with a second embodiment.

In the semiconductor device of this second embodiment, the transistor (FinFET) 10 and a capacitor 60 are provided on a common support member (insulating layer 3). The transistor 10 is the same structure as the transistor in the first embodiment. In the capacitor 60, the silicide layer 15 is provided not only on the top surface of the second fin 51 but also on the side surface of the second fin 51.

In this embodiment, the sidewall 14 provided on the side surface of the second fin 51 is removed after forming source S and drain D in the first fin 11 as in the process shown in FIG. 12.

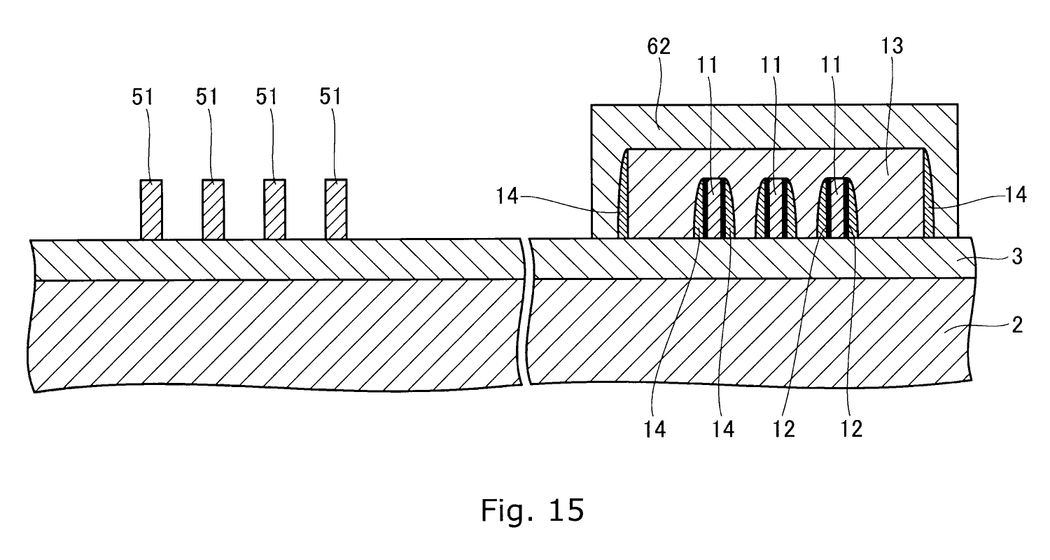

As shown in FIG. 15, the sidewall 14 provided on the side surface of the second fin 51 is removed by etching using phosphoric acid or the like with the first fin 11, the gate electrode 13 and the sidewall 14 in the transistor 10 are covered with the resist 62. Later that, the insulating layer 12 on the second fin 51 is removed.

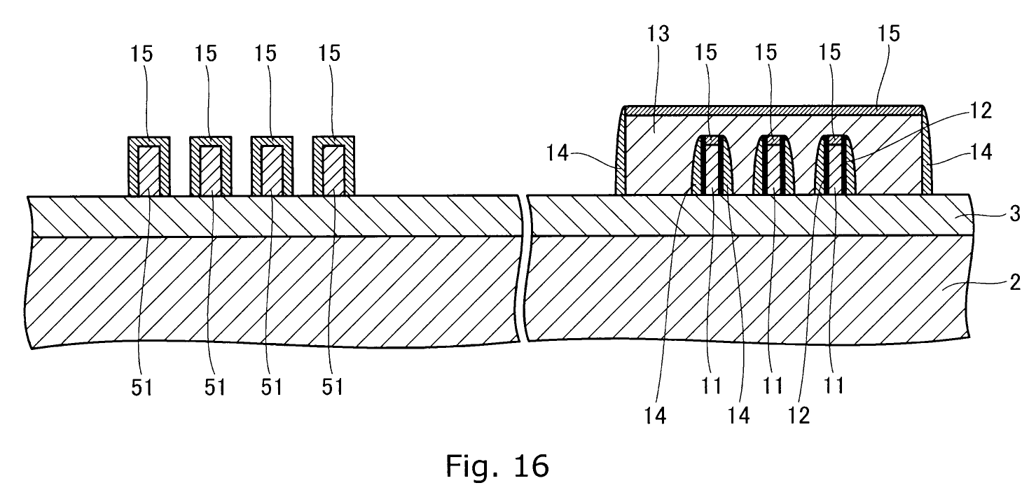

After the resist 62 is removed, the silicidation process is provided as shown in FIG. 16. A metal layer is provided on the entire surface of the insulating layer 3 so as to cover the first fin 11, gate electrode 13 and the second fin 51. Later that, a heat treatment is provided and the metal and Si is reacted. So the silicide layer 15 is provided on the gate electrode 13, a part of the first fin 11 on which the gate electrode 13 is not provided, and the top surface and the side surface of the second fin 51.

In this embodiment, the parasitic resistance of the electrode of the capacitor 60 is reduced, since the second fin 51 which is function as the electrode of the capacitor 60 is covered with the silicide layer 15.

Embodiments of the invention have been described with reference to the examples. However, the invention is not limited thereto.

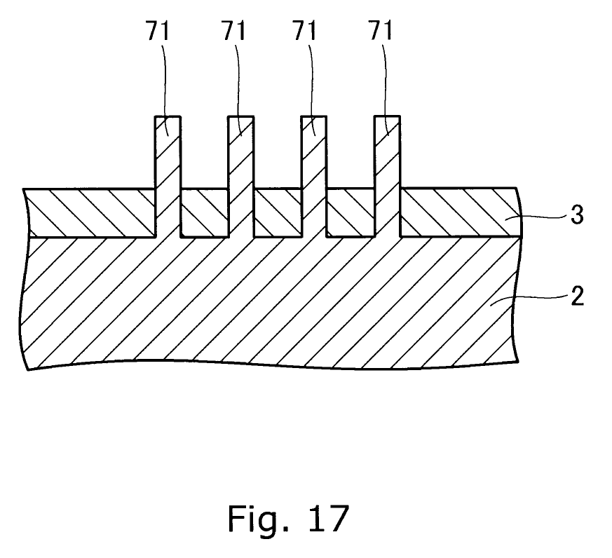

For example, in the first embodiment and the second embodiment, the support member of the first fin 11 and the second fin 51 is the insulating layer 3. However, the support member may be the semiconductor substrate 2 as shown in FIG. 17. Namely the fin 71 is protruded from the semiconductor substrate 2 and the insulating layer 3 is functioned as isolation.

In this case, it may be necessary to prevent the short circuit between the fins 71 for the capacitor electrode. For example, the resistivity of the fins is increased by introducing the impurity into the protruded portion from the insulating layer 3 and not introducing the impurity into the fin 71 lower than the insulating layer 3. The upper portion of the fin 71 and the lower portion of the fin 71 are opposite conductivity type in order to increase the resistance value of the fin 71.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor device, comprising:
a support member;
a FinFET provided on the support member, which has a first fin, a source region provided in the first fin, a drain region provided in the first fin, and a gate electrode provided on the first fin via an gate insulating layer; and
a capacitor provided on the support member, which has a second fin, a third fin and a dielectric layer provided between the second fin and the third fin.

2. A semiconductor device of claim 1, wherein the first fin, the second fin and the third fin are substantially same width and height.

3. A semiconductor device of claim 1, wherein the second fin is extended to substantially parallel with the third fin.

4. A semiconductor device of claim 2, wherein the second fin is extended to substantially parallel with the third fin.

5. A semiconductor device of claim 3, wherein the first fin is extended to substantially parallel with the second fin and the third fin.

6. A semiconductor device of claim 3, wherein a contact of the second fin is provided on a side in a plan view and a contact of the third fin is provided on an opposite side in a plan view.

7. A semiconductor device of claim 4, wherein a contact of the second fin is provided on a side in a plan view and a contact of the third fin is provided on an opposite side in a plan view.

8. A semiconductor device of claim 4, wherein an electrode pad of the second fin is provided on a side in a plan view and an electrode pad of the third fin is provided on an opposite side in a plan view.

9. A semiconductor device of claim 1, wherein a sidewall which is made of an insulating material is provided on a side surface of the second fin and between the dielectric layer and the second fin.

10. A semiconductor device of claim 1, wherein a insulating layer which is substantially same as the gate insulating layer on the first fin is provided on a side surface of the second fin and between the dielectric layer and the second fin.

11. A semiconductor device of claim 1, wherein a silicide layer is provided on a top surface of the second fin and the third fin.

12. A semiconductor device of claim 1, wherein a silicide layer is provided on a top surface and a side surface of the second fin and the third fin.

13. A semiconductor device of claim 1, wherein a support member is a semiconductor substrate.

14. A semiconductor device of claim 1, wherein a support member is an insulating layer on a semiconductor substrate.

15. A semiconductor device of claim 1, wherein an impurity is implanted in the second fin and the third fin.

16. A semiconductor device of claim 1, wherein the first fin, the second fin and the third fin are made of a semiconductor.
